(19) United States
(12) Patent Application Publication
(10) Pub. No.: US 2006/0006945 A1
(43) Pub. Date: Jan. 12, 2006

(54) Parallel amplifier configuration with power combining and impedance transformation

(76) Inventors: Lawrence M. Burns, Los Altos, CA (US); Chong L. Woo, Fremont, CA (US)

Correspondence Address: Terry McHugh;Law Offices of Terry McHugh, PMB 560, 101 First Street, Los Altos, CA, 94022, US

(21) Appl. No.: 10/888,044

(22) Filed: Jul. 8, 2004

(51) Int. Cl. H03F 3/68

(52) U.S. Cl. 330/295

(57) ABSTRACT

A power amplifier uses parallel amplification and at least two levels of power combining to manage peak-to-peak voltage swings, so as to reduce the likelihood of voltage breakdown at individual transistors. Each level of power combining provides an upward impedance transformation. For example, both levels of power combining may double the impedance output relative to the impedance input, so that the impedance at the amplifier output is four times the input impedance. For an embodiment in which the second level is a quadrature power combiner, load reflections of the amplifier may be terminated at an isolation port. In addition, energy levels of the load reflections may be monitored.

### TECHNICAL FIELD

The invention relates generally to signal processing and more particularly to providing power amplification to input signals.

### BACKGROUND ART

There are a number of concerns which must be addressed in the design and fabrication of circuitry for power amplification, such as the power amplifier of a wireless communication device. For such a device, the concerns include ensuring sufficient gain, providing efficiency with respect to converting direct current (DC) power to radio frequency (RF) output power, establishing breakdown voltage conditions that are sufficiently high to enable long term use of the device, and achieving reliable on-off performance of switching circuitry in switching-class power amplifiers. Currently, there is a desire to use low cost, standard digital complementary metal oxide semi-conductor (CMOS) circuitry for radio functions. This desire magnifies potential problems, because CMOS circuitry typically has very low breakdown voltages.

There are two modes of breakdown voltages which should be considered. The first type of breakdown is junction breakdown. Excess electrons or holes are generated by high electric fields, creating an unwanted flow of current across the device. Eventually, a point is reached where the current actually increases, even as the voltage begins to drop (due to discharge of the anode). This “negative resistance” action allows an increasing current to flow, until excessive heat is generated. Eventually, permanent damage will occur. The second type of breakdown is across an oxide. In MOS processes, the gate of a transistor is insulated by an oxide layer from its drain, source and bulk nodes. Whenever a forward voltage is placed on the gate, there is a potential for breakdown across the oxide, in which the gate can short to the source, drain or bulk regions of the MOSFET. Even if no breakdown occurs across the gate, a long-term threshold voltage shift can occur, which causes the characteristics of the MOSFET to shift, if the gate-source voltage is kept too high for a long period of time.

Power levels commonly used in wireless RF communication devices can result in relatively large voltage swings. For example, at a power level of 4 watts, in order to obtain +36 dBm of transmitted output power on 50 ohm transmission lines, a signal of 40 volts, peak-to-peak may be required. It is likely that conditions are worse for poorly matched loads that are not at the nominal 50 ohm load impedance. The large voltage swings are a problem for modern, high speed semiconductor devices, which typically operate at power supply voltages of only a few volts, with the situation being particularly problematic for sub-micron CMOS integrated circuits which must operate at very low power supply voltages. Part of the problem results from the need to efficiently convert DC power to RF output power. For a single-ended power amplifier circuit running in class A mode, the efficiency may be approximately 50 percent. The class A amplifier is very linear and relatively free of distortion, but is less efficient than a class B amplifier, wherein the efficiency may be 78 percent.

In both the class A and class B modes of operation, transistors of a power amplifier have a linear relation in terms of input-to-output power. This linear operation generally results in a somewhat lower efficiency. If the transmitted signal is constant envelope (or if a modulator is used to take advantage of polar modulation methods), non-linear switching mode amplifiers may be used. One example of such an amplifier is the class E amplifier, which operates as a switching amplifier. That is, the transistors of class E amplifiers operate as switches, turning “on” and “off” during operation. In the case of class E amplifiers, a matching network may be employed to ensure that the switch only operates when the voltage across the transistor is zero, so that there are minimum losses during the switching transitions. This mode of operation can allow efficiencies approaching 100 percent. A class D amplifier is another switching-class power amplifier that works by adjusting its duty cycle in proportion to the input waveform. Unfortunately, while the switching-class power amplifiers are highly efficient, they tend to have lower gain than class A or class B amplifiers. When the gain of the power amplifier is low, it requires more power from the input to turn “on” the output device. This input power reduces the efficiency of the RF system in which the power amplifier is a part. For this reason, the term “power added efficiency” (PAE) has been used as a more accurate reference to the efficiency, since the measurement takes into account input power needed to operate the switches. In general, power amplifiers with higher gain have higher PAE.

Another categorization of power amplifiers is one in which the amplifiers are identified as having either a single-ended configuration or a differential configuration. In the single-ended configuration, a single input signal, generally referenced to ground, is amplified. In comparison, differential amplifiers amplify the voltage difference between two input signals. One deficiency of the single-ended amplifier is the fact that the connection to ground for the source of the input transistor must pass through the inductance of a bond wire and package lead for the integrated circuit that includes the amplifier. On the other hand, in the differential configuration, a virtual ground exists at a common connection to the sources of the two input transistors. As a result, only DC current flows through the grounded bond wire from the sources. In practice, the current in the transistors is not exactly equal and opposite, but most of the beneficial effects are still achieved.

While the above-described configurations of power amplifiers operate well for their intended purposes, further advances are available.

### SUMMARY OF THE INVENTION

A parallel amplifier configuration that provides impedance transformation enables management of peak-to-peak voltages in a power amplifier. The power amplifier utilizes multiple amplifier stages and at least two levels of power combining.

In the first embodiment, first and second amplifier stages are connected to receive first inputs, while third and fourth amplifier stages receive second inputs that are generally 90 degrees out-of-phase with the inputs of the first and second amplifier stages. A first power combiner receives signals from the first and second amplifier stages to generate a phase-dependent output. Similarly, a second power combiner receives the outputs of the third and fourth amplifier stages and generates a second phase-dependent output that is generally 90 degrees out-of-phase with the first phase-dependent output. A quadrature power combiner inputs the first and second phase-dependent outputs and generates the output of the power amplifier. An advantage of this embodiment is that the quadrature power combiner is easily adapted to direct load reflections to an isolation connection, such as a load resistor connected to an isolation port of the combiner. For applications in which the power amplifier is used to generate signals to be transmitted via an antenna, the load reflections are undesired signals from the antenna connection to the quadrature power combiner. Optionally, the power amplifier includes monitoring circuitry to detect energy levels of the reflections.

Within the first embodiment, the first and second power combiners provide the first level of power combining, while the quadrature power combiner establishes the second level.

In a second embodiment, the first level combination is provided by a pair of in-phase power combiners having outputs that are directed to an out-of-phase power combiner of the second level. Here, the input signals to the third and fourth amplifier stages are generally 180 degrees out-of-phase with the input signals to the first and second amplifier stages. The outputs of the first and second in-phase power combiners are also generally 180 degrees out-of-phase. This out-of-band approach is sometimes referred to as the “push-pull approach” to power combining. An advantage of this embodiment over the first embodiment is that there is no longer a need for quadrature inputs.

In the third embodiment, the inputs to the amplifier stages are in-phase. Thus, the power amplification and the two levels of power combining occur while the signals remain in-phase.

In all three embodiments, the first level of power combining provides a first upward impedance transformation. The second level provides a second upward impedance transformation. For both levels, the ratio may be 1:2, so that the impedance at the output of the amplifier is four times the impedance at its inputs. For example, an input impedance of 12.5 ohms will be converted to an output impedance of 50 ohms. Another common feature among the embodiments is that the inputs to the first level of power combining may be differential, while the outputs are single-ended. Thus, differential inputs to the first level power combining may be converted to single-ended outputs to the second level.

The four or more amplifier stages may be formed on a single integrated circuit chip that is contained within the same integrated circuit package as the components of the two levels of power combining. It has been determined that the invention is well suited for use in power amplifiers for wireless communication devices.

### BRIEF DESCRIPTION OF THE DRAWINGS

FIG. 1 is an illustration of a power amplifier in accordance with one embodiment of the invention.

FIG. 2 is an illustration of a power amplifier having current monitoring capability in accordance with the invention.

FIG. 3 is one example of a circuit for providing breakdown-related voltage detection.

FIG. 4 is one example of circuitry for providing over-voltage protection.

FIG. 5 is an illustration of a segmented power amplifier in which each segment has an alternative load capability.

FIG. 6 is an illustration of the use of a balun as an impedance matching network.

FIG. 7 is an illustration similar to FIG. 6, but with a single-ended output.

FIG. 8 illustrates an alternative to FIG. 6.

FIG. 9 illustrates how the balun can be made physically small with capacitive loading.

FIGS. 10, 11 and 12 illustrate alternative approaches to providing amplification and signal combination.

FIG. 13 illustrates the use of a quadrature hybrid balun for terminating reflections from the load.

FIG. 14 illustrates an arrangement for monitoring reflections of signals transmitted via a power amplifier.

### DETAILED DESCRIPTION

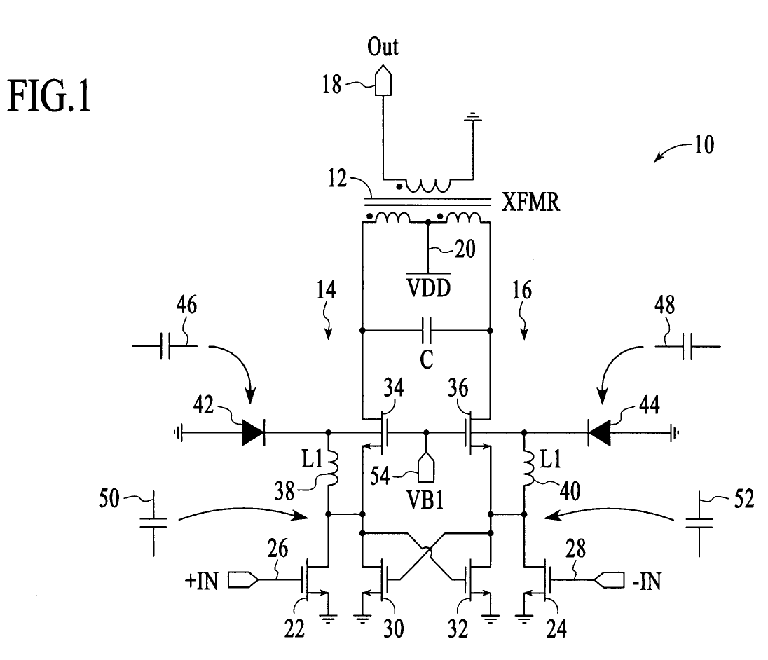

In the preferred embodiment of the invention, a cascode topology with deep-NWELL transistors is used to improve the breakdown voltage of a power amplifier 10. The approach allows for much higher signal swings at the power amplifier output, resulting in a higher transmitted power and an increased efficiency. As an additional feature, inductances may be added in order to resonate out excess capacitance at connections of transistors. While FIG. 1 shows one possible embodiment of the invention, modifications may be made without diverging from the invention. For example, the transformer 12 may be replaced with another type of impedance transforming network, such as a balun or a broadband transmission line transformer.

The embodiment of FIG. 1 employs a differential configuration in which a first amplifier stage 14 cooperates with a second amplifier stage 16 to define the RF amplifier output 18 at the secondary of the transformer 12. While not shown in FIG. 1, it is typical to use matching circuits at either or both of the primary and secondary sides of the transformer. A differential configuration of the output inductors and the matching circuits can be achieved by using a center-tapped transformer, as shown. Here, the center tap 20 is connected to VDD, as a convenient means to provide bias voltage to the output transistors.

An advantage of a differential amplifier is that it reduces the voltage swing at individual transistors, since only one half of the total voltage is provided across each transistor drain. Even lower voltage swings are available if different turn ratios are provided in the transformer to provide for a lower impedance at the drains of the output transistors. Basically, the power amplifier 10 swings larger currents at lower voltages in the transformer primary with corresponding large voltage swings and lower current swings at the secondary. Connection of the center tap 20 ensures that the swings are centered at VDD.

As previously described, efficiency is promoted by using switching-class power amplifiers, such as class D or class E amplifiers. Unfortunately, such amplifiers have lower gain than class A or class B amplifiers. When the gain of a power amplifier is low, it requires more power from the input to turn “on” the output devices. This input power reduces the efficiency of the overall power amplifier. However, the power amplifier 10 of FIG. 1 addresses this problem by adding negative resistance across the transistors 22 and 24 connected to receive the inputs 26 and 28. The transistors 22 and 24 will be referred to as the “input” transistors since they receive the input signals for driving the power amplifier.

The negative resistance is provided in the embodiment of FIG. 1 by a pair of cross-coupling transistors 30 and 32. The cross-coupling transistors are in a parallel connection with the input transistors 22 and 24. For each amplifier stage 14 and 16, this parallel connection is in series with a single cascode transistor 34 and 36. By adding sufficient negative resistance, oscillation is promoted. The amount of negative resistance can be adjusted by using different ratios of transistor area in the cross-coupled pair (transistors 30, 32), as compared to the input transistor pair (transistors 22, 24). Despite the fact that the amplifier operates in a very non-linear switching-mode, this mode of operation is tolerable, and actually preferred, in many applications. In the configuration shown in FIG. 1, the circuitry below the cascode devices 34 and 36 may be considered to consist of a cross-coupled pair (negative resistance) with parallel helper transistors. If the negative resistance is high enough, oscillation occurs, resulting, in essence, in an injection-locked oscillator. The lower devices swing between 0V and VDD, limiting the stress on themselves and allowing the cascode devices to operate at a lesser signal swing. The injection-locked oscillator approach uses positive feedback (brought about by the addition of the negative resistance) to achieve increased gain, reducing the drive requirements in the preceding stage. Thus, there is an improved PAE. In general, switching amplifiers, with or without positive feedback, are adjustable in power output by simply varying the VDD voltage. Maximum power is achieved when VDD is at a level that results in signal swings just below breakdown. Minimum power is achieved when VDD is near zero. An advantage of the switching amplifier configuration is that the output match does not have to be re-tuned when VDD changes.

An alternative to the connection shown in FIG. 1 would be to connect the gates of the cross-coupled pair 30 and 32 to the drains of the cascode devices 34 and 36. However, this could potentially create excess voltage across the gates of the cross-coupled pair. A safer approach is the one shown in FIG. 1, wherein the gates of the lower pair are connected to the sources of the cascode devices 34 and 36. This ensures that the gate-source junctions are not overdriven, reducing the issues involving gate-oxide breakdown.

In addition to addressing the issues involving gate-source and drain-source junction breakdowns, breakdowns at the junctions to the bulk nodes are considered. Furthermore, each bulk node of one of the cascode devices is connected to a source of the same transistor for maximum transconductance. Ideally, the bulk node of a cascode transistor is at AC ground and is, at the same time, connected in a DC sense to the source in order to maintain maximum transconductance.

In the power amplifier 10, an inductor 38 and 40 is connected from the bulk node of each cascode device 34 and 36 to the source node of the same device. The low DC impedance of the inductor connects the source and bulk nodes at low frequency. Since the bulk nodes of the cascode devices are very large areas, there is significant capacitance to ground, via the parasitic reverse-biased diodes 42 and 44 formed by the bulk (referred to as RWELL) and the substrate on which the devices are fabricated. The large diodes function as AC decoupling capacitors to ground at the bulk nodes of the cascode devices. In yet other implementations, separate capacitors are added to further ensure the bulk nodes of the cascode devices are truly at AC ground. As shown, there are parasitic capacitances 46, 48, 50 and 52 (associated with the transistors and diodes) which affect the operations of the inductors 30 and 40 and the reverse-biased diodes. In operation, the action of the inductors resonates out excess capacitance at the connections of the sources of the cascode devices 34 and 36 to the transistor pairs below the cascode devices. The end result is a significant improvement with respect to breakdown characteristics, with a significant improvement in high-frequency operation, compared to implementations without said inductors.

The likelihood of breakdown can also be reduced by setting a lower VDD. In the power amplifier 10, VB1 54 also functions as a control signal for voltage breakdown. VB1 is provided to the gates of the cascode devices independently of current through the series connections of the transistors 22, 30 and 34 of the first amplifier stage and independently of current through the transistors 24, 32 and 36 of the second amplifier stage 16. VB1 is set to a level such that both the upper cascode devices (transistors 34, 36) and the lower transistors (22, 30, 32 and 24) are maintained at a voltage below breakdown.

As compared to power amplifiers having more cascode devices, the limitation of a single cascode device 34 and 36 to each amplifier stage 14 and 16 significantly increases the efficiency of the power amplifier 10, by virtue of the fact that a single transistor can have lower resistance when fully switched on.

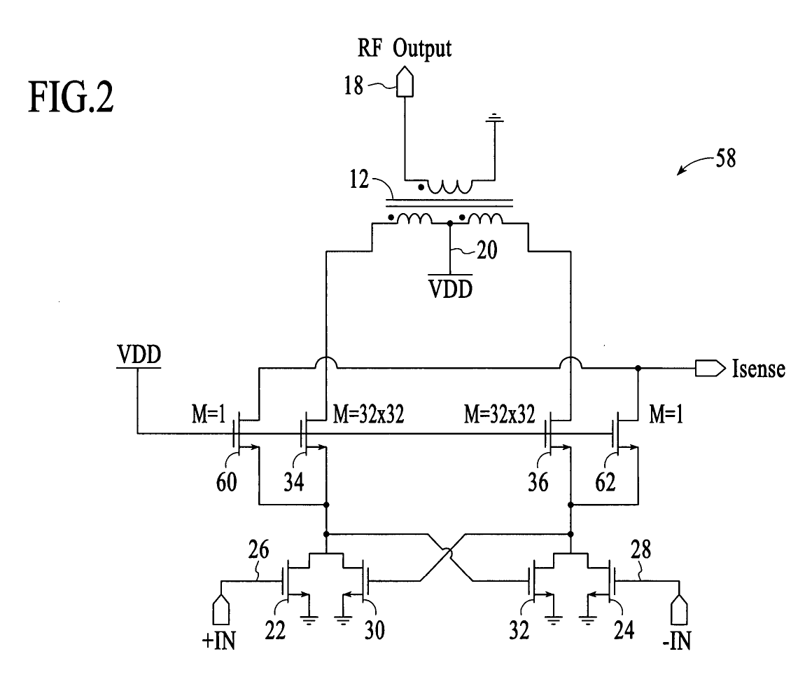

Thus, the power amplifier 10 includes a number of features which are designed to minimize the likelihood of voltage breakdown at a transistor. Additionally, the circuit shown in FIG. 2 allows the current to be sensed in the output stage. By knowing the current flowing in the output stage along with the knowledge of VDD, the output power can be accurately determined. This is done by connecting small MOSFET devices 60 and 62 in parallel to the cascode devices 34 and 36. For first-order approximation, two MOSFETs having the same gate-source voltages will have the same current flowing in them. This current-mirror action can be used as a means the indirectly sense signal current. Nevertheless, some risk remains, particularly under poorly matched load conditions. Therefore, the power amplifier 58 of FIG. 2 is designed to enable monitoring of the peak voltage at the output drain nodes of the cascode devices 34 and 36. When the peak voltage exceeds a preselected threshold, preventive steps are triggered. For example, VDD can be reduced or the input drive can be reduced. This action will prevent excessive voltage across the output devices. In FIG. 2, the components which are functionally identical to those of FIG. 1 are provided with the same reference numerals. Monitoring is achieved by inclusion of a pair of monitoring transistors 60 and 62 connected to the cascode devices 34 and 36. The gates of these four transistors are connected to VDD. The drains of the monitoring transistors provide the sense signal output 64, which is used to determine when the corrective action is to be triggered. Thus, the current is sensed by the parallel small devices across the relatively large cascode devices. When the signal is combined with information regarding load reflections and the known value of VDD, an accurate transmit power estimate can be established for a wireless communication device. Additionally, since VDD is known, if the output matching elements exhibit tight tolerance, output power can be very accurately determined. Other factors to consider are finite output conductance and any variations in the bias of the gates of the cascode devices. These factors can determine the accuracy of the sense measurements and the efficiency at low VDD levels.

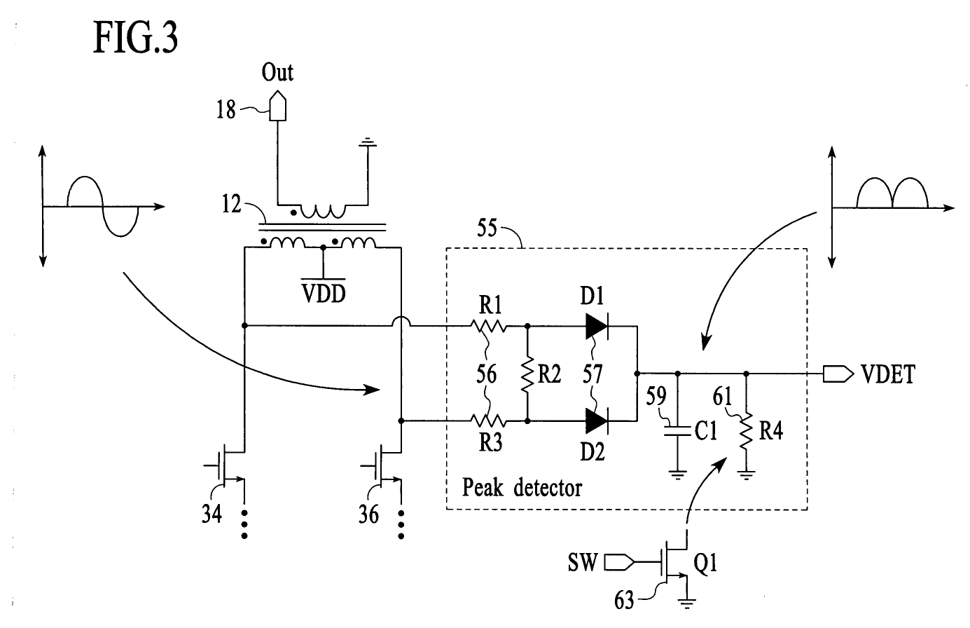

FIG. 3 is one possible embodiment of a peak voltage detector circuit 55. In this embodiment, a simple diode detector is connected to the drains of the cascode devices 34 and 36. Resistors 56 are used to create larger impedances between the diodes and the output stage to ensure that the output is lightly loaded. The peak voltage on a capacitor 59 may be bled off via a resistor 61, which provides fast attack and slow decay. Alternatively, the peak voltage can be shunted to ground at the end of a packet of data by use of a switching transistor 63, which can be used in place of resistor 61. The use of a transistor to discharge the peak voltage detection capacitor 59 will require additional circuitry, not shown, to coordinate its turn-on and turn-off.

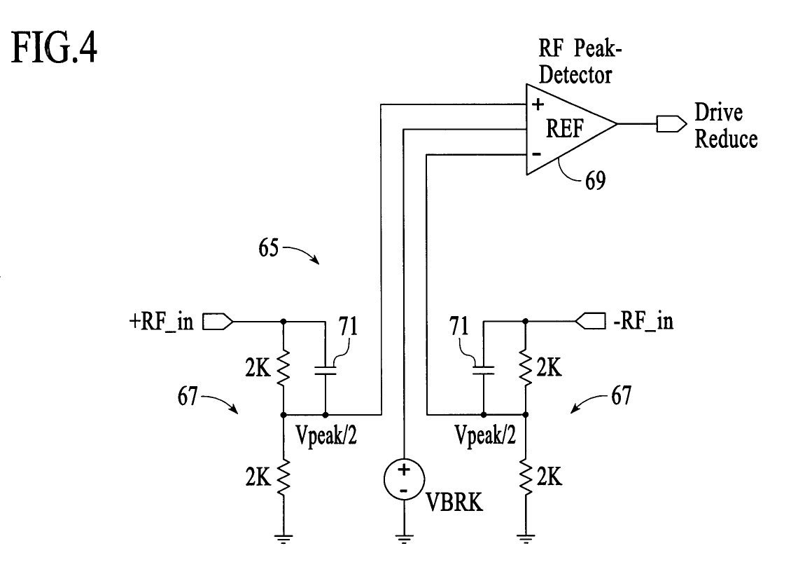

FIG. 4 is an embodiment of an over-voltage protection circuit 65. The circuit can be connected across the drains of the cascode devices 34 and 36 of FIGS. 1 and 2. Resistor dividers 67 accurately reduce the voltage swings to levels acceptable to an RF peak detector 69. When the peak detector determines that the voltage swings are too high, a “drive-reduce signal” can be generated to reduce the levels of the drive signals to the input transistors 22 and 24 of FIGS. 1 and 2 or, alternatively, to reduce the VDD on the power amplifier. Small “speed-up” caps 71 may be required to maintain sufficient bandwidth. An important aspect of the circuit is that it should be a very light load on the power amplifier output, so that high efficiency is maintained.

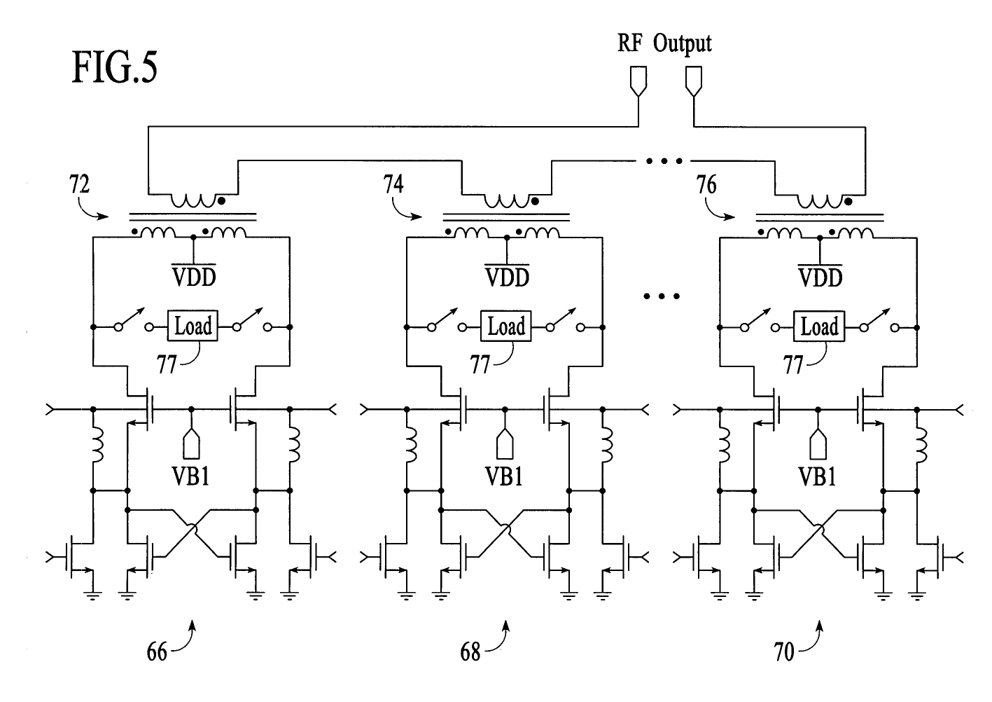

A strategy for addressing the limited power-handling capability of CMOS devices is shown in FIG. 5. Here, simplified schematics of parallel amplifiers 66, 68 and 70 that are consistent with the power amplifier of FIG. 1 are shown as providing a parallel amplifier topology that limits voltage, current and local power dissipation. Any number of parallel amplifiers can be used to achieve the desired power reduction per amplifier stage, although constraints due to the routing of RF lines on-chip and the need for coordinated control of the stages generally result in the number of stages ranging between four and eight, in practice. The benefits of a 1:N step-up in the transformer can be achieved by connecting the secondary windings of multiple 1:1 transformers in series, although said transformers could use other impedance ratios, in practice. The individual parallel differential stages 66, 68 and 70 provide the desired 1:N step-up, with N being the number of stages. A concern with the use of flux-coupled transformers is that such transformers may suffer from poor magnetic coupling between the primary and secondary of each transformer 72, 74 and 76, thereby limiting bandwidth, adding insertion loss, and providing an imbalance induced by the grounded node on the secondary of the last stage. All of these unwanted effects reduce power and efficiency. Another concern with this approach is that it requires a large die area for fabrication and is somewhat difficult in the connections to VDD, unless a center-tap configuration is used. Another advantage of using multiple parallel amplifiers is that any one section of the amplifier can be powered on or off, individually. This allows the output power to be set in discrete steps, thus providing for better efficiency at lower power settings. For example, maximum power is achieved when all sections are turned on and minimum power is achieved when only one section is turned on. In general, it is desirable to ensure that the load being presented to each input of the balun remains the same whether the stage is turned on or off. This can be accomplished by using a switch-able load circuit 77, shown in FIG. 5. Note that power level adjustments between discrete power settings, as determined by the number of stages turned on at a given time, are effected by varying the VDD voltage, as described earlier.

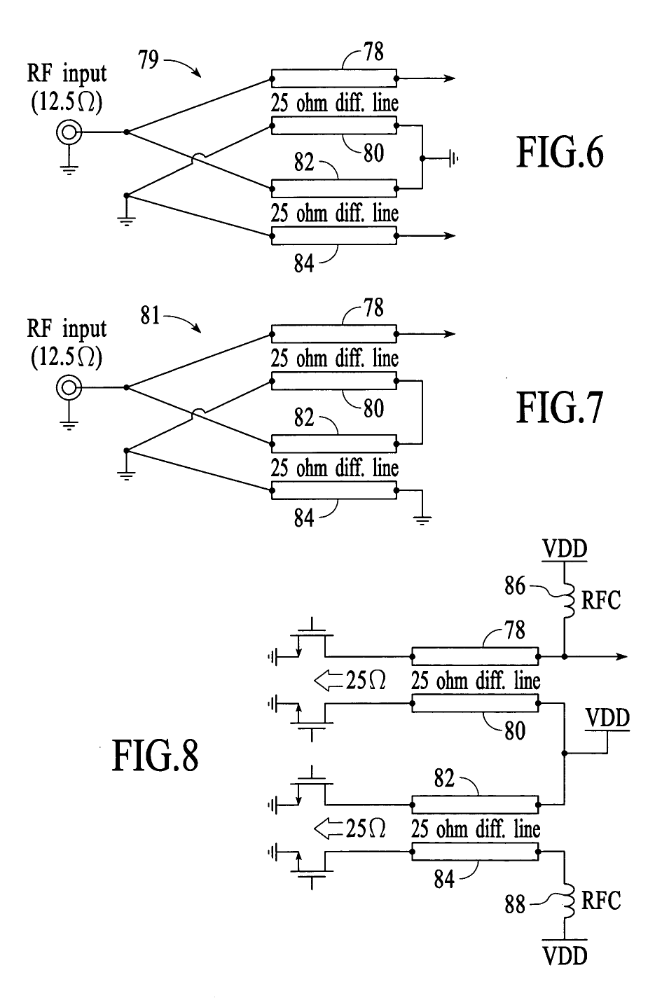

One approach to alleviating the unwanted effects resulting from reliance on magnetic coupling in the transformers is to replace the “flux coupled” transformers with transmission line transformers. This is shown in FIGS. 6, 7 and 8. In FIG. 6, by using two pairs of coupled lines 78, 80, 82 and 84, low loss, broadband transmission line transformers can be fabricated. The transmission line transformers rely on both inductive and capacitive coupling. Bandwidths can exceed three decades in practice, with losses approaching 0.1 dB. The coupled lines can consist of edge-to-edge coupled lines, as shown in FIG. 6, or can consist of over-under coupled lines. Different configurations of transmission-line transformers can be designed, depending on the impedance transformation desired and the need for balanced-to-unbalanced operation.

The particular transformer shown in FIGS. 6, 7 and 8 is referred to as the Guanella balun. The action of this circuit both transforms impedance and does the balanced-to-unbalanced transformation of the signal.

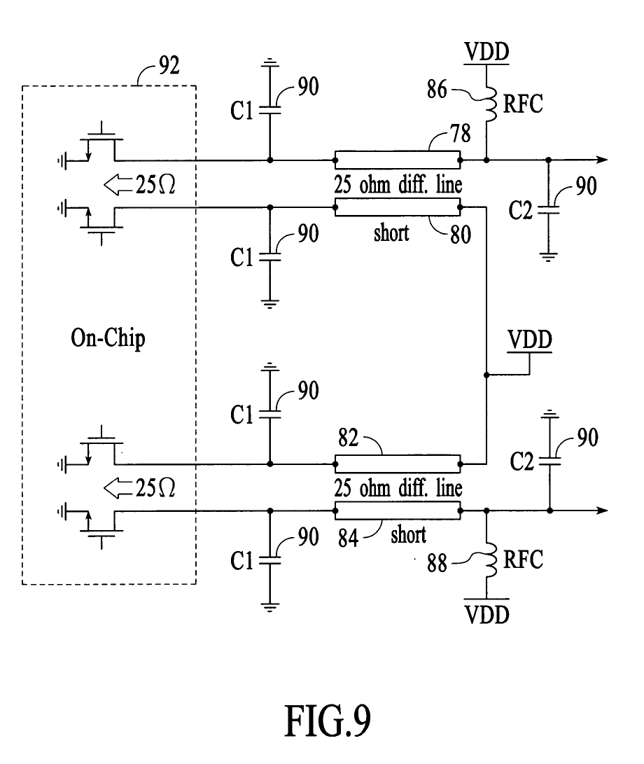

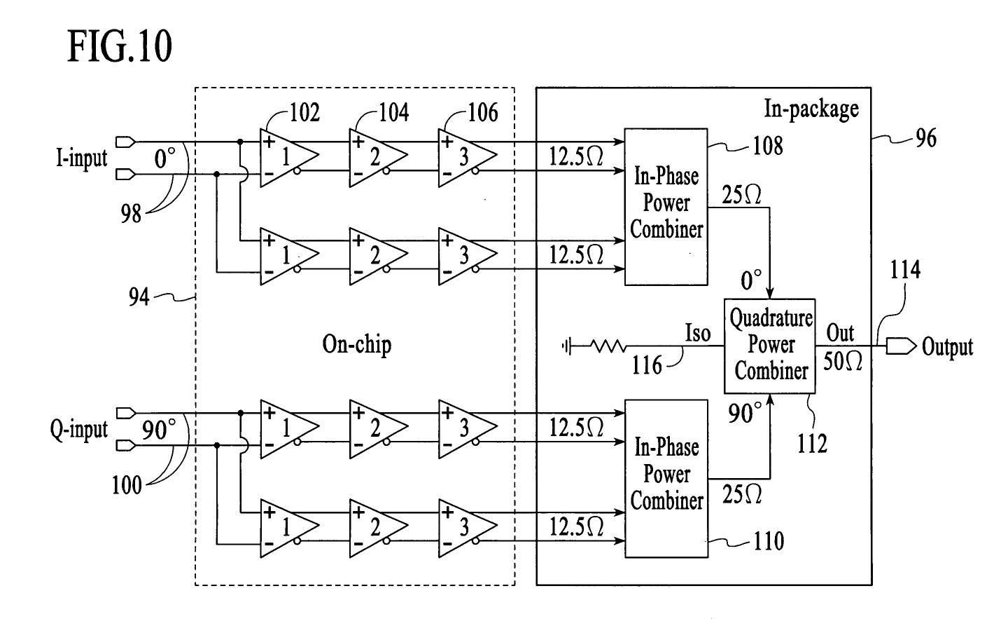

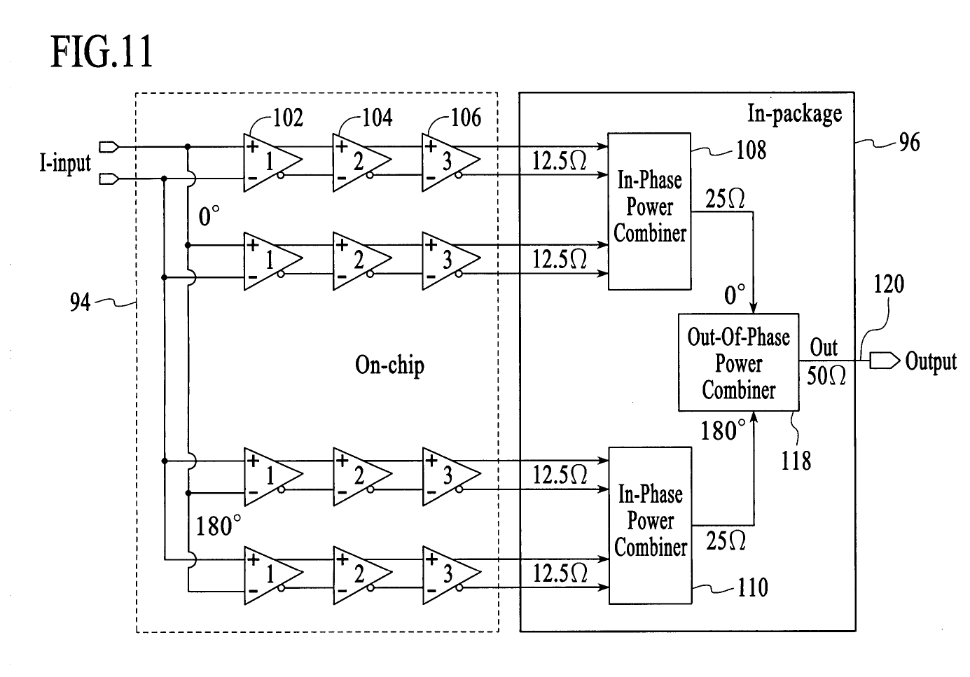

The action of the Guanella balun 79 of FIG. 6 steps up the input voltage by a factor of two and steps up the impedance by a factor of four. Thus, with the input impedance of 12.5 ohms in FIG. 6, the stepped up output impedance is 50 ohms. Other impedances can be used with such baluns, but the 1:4 action remains the same. For example, an input impedance of 6.25 ohms can be obtained with a 25 ohm output impedance. Note that FIG. 6 shows the output of the balun being taken differentially, which can be a benefit in some applications. FIG. 7 shows a more typical use of the Guanella balun 81, wherein the ground connection is removed from between nodes 82 and 80 and placed on node 84. This allows for a balanced (differential) input to the balun and an unbalanced (or single-ended) output from the balun. The importance of this issue will be discussed more in reference to FIGS. 8 and 9.

One challenge with the Guanella balun involves connecting VDD. This can be accomplished in a variety of ways, including using RF chokes 86 and 88, as shown in FIG. 8. Alternatively, the connections for VDD may be brought from the circuitry that follows the balun. It has been found that it is important to maintain nearly perfect balance at the final power amplifier stage outputs for optimum efficiency and acquiring the highest power output. The action of the Guanella balun meets these requirements more readily than the transformer-coupled circuitry described above. In general, this means that the final power combiner (not shown) which takes outputs from the baluns (as shown in FIG. 8) needs to do a final balanced-to-unbalanced transformation. FIG. 9 is a modification of the circuitry of FIG. 8. While distributed elements tend to have low loss and wide bandwidth, they also tend to be physically large. The physical size of such elements can be greatly reduced by using surface-mounted components to “capacitively load” the transmission lines 78, 80, 82 and 84. The capacitive loading is represented by six capacitors 90 in FIG. 9. Note that the VDD node is assumed to be an AC short, thus not requiring additional capacitors to ground. The capacitive loading generally reduces bandwidth. However, for applications which can afford to sacrifice some bandwidth, the transmission lines can be made physically shorter by capacitively loading the ends of the lines with lumped capacitors 90. The shorter transmission lines are far more attractive for integrated assemblies, such as those which are used in cellular telephones and other wireless communication devices. Only the transistors need to be on-chip, where the integrated circuit chip is represented by box 92.

In a fashion similar to the one described with reference to FIG. 3, outputs of baluns can be combined to sum the output power from a collection of parallel amplifier stages. Thus, using a number of parallel stages allows each stage to operate at a lower individual power level, and therefore at lower voltage swings. For example, four parallel amplifier stages may be combined to be a quadrature balun. As will be explained more fully below, the combination may be with zero degree or ninety degree inputs. The combination could be in-phase or push-pull, or other power combining techniques may be used. The amplifier stages can be turned off in a one-by-one manner to lower the total output power with no efficiency loss. This feature maintains a high efficiency over a large range of output power levels and is often vital to obtaining the most “talk time” from a battery within a cellular telephone.

As another possibility, two or more Guanella baluns may be connected to a final power combiner. Each Guanella balun is coupled to cooperative amplifier stages as described above. In this embodiment, the inputs to the final power combiner (e.g., a final balun) may be either differential or single-ended.

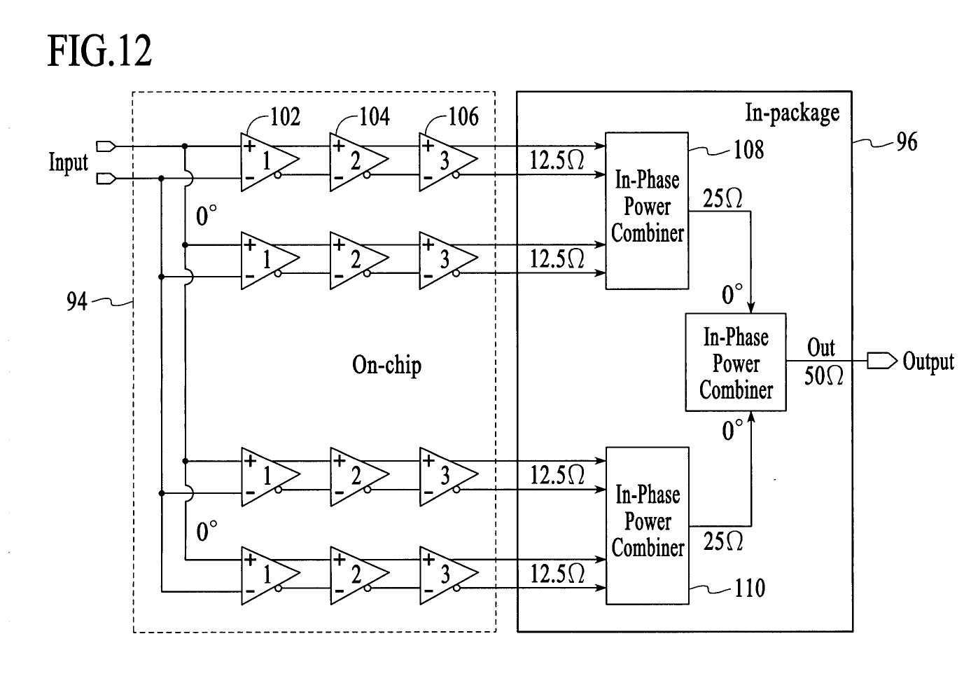

As previously noted, the voltage across a 50 ohm load, with four watts of power, can reach 40 volts, peak-to-peak. Also noted was the fact that parallel amplifier configurations may be used to alleviate the concerns. FIGS. 10, 11 and 12 show different baseline parallel amplifier configurations. In each embodiment, a first box 94 encloses components which are contained on a single integrated circuit chip, while a second box 96 encloses components that are off-chip but which can be within the same integrated circuit package as the components of box 94. However other arrangements are contemplated. In the embodiment of FIG. 10, the inputs 98 and 100 are 90 degrees out-of-phase, which eventually requires a 90 degree phase shift in the power combining components at the output of the power amplifiers. Each of four parallel amplifier strings comprises three amplifiers 102, 104 and 106. Optionally, a different number of amplifiers may be employed in each string. The on-chip components provide four 12.5 ohm inputs for a pair of in-phase power combiners 108 and 110. The outputs of the in-phase power combiners define 25 ohm inputs to a quadrature power combiner 112. Thus, the in-phase power combiners both transform impedances and convert differential inputs from the differential amplifiers 106 to establish single-ended outputs. The two single-ended outputs from the in-phase power combiner are used to define the 50 ohm output 114. The quadrature power combining approach has the advantage that load reflections can be terminated at an isolated (“Iso”) port 116.

In the approach of FIG. 11, out-of-phase power combining is used. This approach is sometimes referred to as the “push-pull approach.” As in FIG. 10, the outputs of two upper power amplifier stages are combined using the in-phase power combiner 108, while the signals from the two lower amplifier stages are combined by the in-phase power combiner 110. However, in this approach, the signals from the upper amplifier stages are connected in-phase (0 degrees), while the signals from the two lower amplifier stages are connected out-of-phase (180 degrees). An out-of-phase power combiner 118 defines the 50 ohm output 120. This approach avoids the need of quadrature inputs, but does not have the advantages of the isolated port to eliminate load reflections.

The approach of FIG. 12 is similar to the configuration of FIG. 11, but the final power combiner 122 is an in-phase component, since the preliminary power combiners 108 and 110 provide a pair of in-phase (0 degrees) signals. Thus, both the inputs and outputs of the stages of power amplifiers 102, 104 and 106 are connected (and combined) in-phase. Similar to the approach of FIG. 11, the in-phase approach of FIG. 12 does not have the advantage of the isolated port.

For configurations such as that of FIG. 10 in which quadrature inputs are used, the inputs may be obtained from a 0°/90° power splitter or may be obtained from in-phase and quadrature signals that are available from other components of the integrated circuit chip. However, the advantage of acquiring the in-phase and quadrature components directly from the chip is that it eliminates the need of an input 0°/90° power splitter.

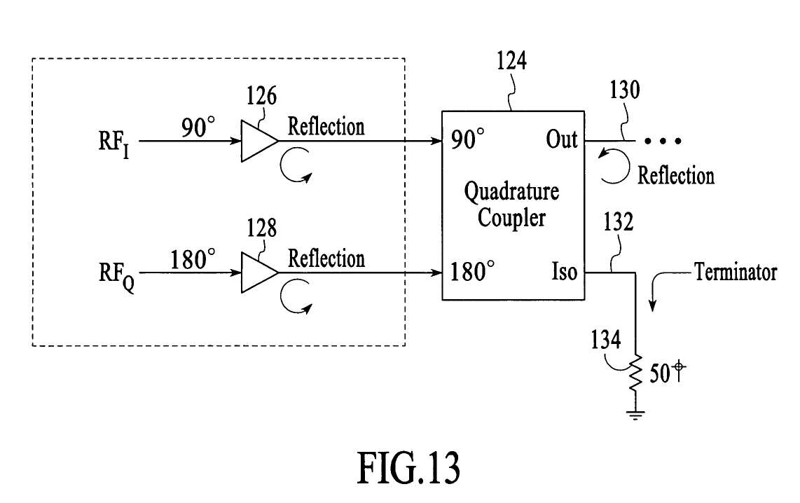

For approaches in which the isolation port is available, reflections can be terminated in the manner shown in FIG. 13. A quadrature coupler (sometimes referred to as a “hybrid coupler”) 124 is connected to receive the in-phase signal component (RF_{I}) and the amplified quadrature signal component (RF_{Q}) from amplifiers 126 and 128. The quadrature couple includes its output port 130 and its isolation port 132. If the circuitry is part of a transceiver that is operated near a structure which reflects the output frequency, the reflections will be redirected to the isolation port and terminated using a 50 ohm termination resistor 134.

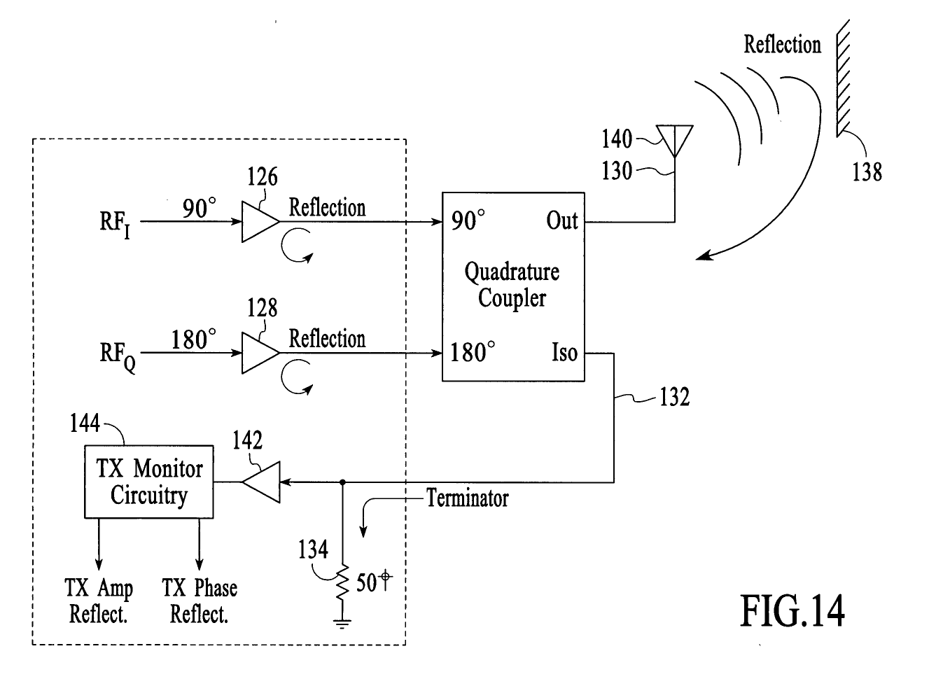

Alternatively, the “information” at the isolation port 132 may be used as the basis to monitor the reflected energy at the output port 130. This is represented in FIG. 14. Reflections from a structure 138 return an antenna 140 connected to the output port 130. The isolation port is connected to the termination resistor 134 and to a reflection amplifier 142. The amplified reflection signal is directed to monitoring circuitry 144 which generates data indicative of both the amplifier reflection and the phase reflection. It is then possible to provide a better idea of the true transmitted output power, as well as a means to enhance the transmission signal back to a receiver at the other end of the link.

What is claimed is:

1. A power amplifier comprising:
first and second amplifier stages connected to receive first inputs having a first phase;
third and fourth amplifier stages connected to receive second inputs having a second phase that is generally ninety degrees out-of-phase with said first phase;
a first power combiner connected to said first and second amplifier stages to generate a first phase-dependent output;
a second power combiner connected to said third and fourth amplifier stages to generate a second phase-dependent output which is generally ninety degrees out-of-phase with said first phase-dependent output; and
a quadrature power combiner connected to receive said first and second phase-dependent outputs, said quadrature power combiner having an amplifier output that is responsive to a combination of said first and second phase-dependent outputs.

2. The power amplifier of claim 1 wherein said quadrature power combiner is configured to direct load reflections to an isolation connection.

3. The power amplifier of claim 2 wherein said isolation connection is coupled to a termination load for terminating said load reflections.

4. The power amplifier of claim 3 wherein said isolation connection is further connected to circuitry configured to monitor energy levels of said load reflections.

5. The power amplifier of claim 4 wherein said amplifier output of said quadrature power combiner is directed via an output port to an antenna, said load reflections being energy received at said quadrature power combiner via said output port.

6. The power amplifier of claim 1 wherein said first, second and quadrature power combiners are cooperative to provide an impedance transformation of said amplifier output as compared to inputs of signals from said amplifier stages.

7. The power amplifier of claim 6 wherein said impedance transformation has a ratio of approximately 1:4, such that said amplifier output is associated with an output impedance that is generally the sum of impedances of the first, second, third and fourth amplifier stages.

8. The power amplifier of claim 1 wherein each said first and second power amplifier is configured to convert differential inputs to a single-ended output, said single-ended outputs of said first and second power amplifiers being said first and second phase-dependent outputs.

9. A power amplifier comprising:
first and second amplifier stages connected to receive input signals having a first phase;
third and fourth amplifier stages connected to receive said input signals having a second phase that is generally 180 degrees out-of-phase with said first input signals;
a first in-phase power combiner connected to said first and second amplifier stages to generate a first combined power output, said first in-phase power combiner providing an upward impedance transformation;
a second in-phase power combiner connected to said third and fourth amplifier stages to generate a second combined power output having a phase that is generally 180 degrees out-of-phase with said first combined power output, said second in-phase power combiner providing an upward impedance transformation; and
an out-of-phase power combiner connected to receive said first and second combined power outputs so as to generate an amplifier output that is responsive thereto.

10. The power amplifier of claim 9 wherein said first, second, third and fourth amplifier stages provide differential outputs and wherein said first and second in-phase power combiners are configured to provide single-ended outputs.

11. The power amplifier of claim 9 wherein upward impedance transformations are defined by a 1:2 ratio of input impedance to output impedance.

12. The power amplifier of claim 11 wherein said out-of-phase power combiner has an impedance transformation with a 1:2 ratio of input impedance to output impedance.

13. The power amplifier of claim 9 wherein each said amplifier stage includes a plurality of differential amplifiers connected in an electrical series arrangement.

14. A power amplifier comprising:
first and second amplifier stages connected to receive input signals having a first phase;
third and fourth amplifier stages connected to receive said input signals having said first phase;
a first in-phase power combiner connected to said first and second amplifier stages to generate a first combined power output;
a second in-phase power combiner connected to said third and fourth amplifier stages to generate a second combined power output, said first and second in-phase power combiner each providing a first upward impedance transformation; and
a third in-phase power combiner connected to receive said first and second combined power outputs so as to generate an amplifier output that is responsive thereto, said third in-phase power amplifier being configured to provide a second upward impedance transformation.

15. The power amplifier of claim 14 wherein each of said first and second upward impedance transformations is defined by a ratio of approximately 2:1.

16. The power amplifier of claim 14 wherein each said amplifier stage includes a plurality of differential amplifiers connected in electrical series.

17. The power amplifier of claim 15 wherein said first and second in-phase power combiners are configured to include differential inputs and a single-ended output.

18. The power amplifier of claim 14 wherein said amplifier stages are integrated onto a single integrated circuit chip.

19. The power amplifier of claim 18 wherein said integrated circuit chip is contained with said in-phase power combiners within a single integrated circuit package
